(19) United States
(12) Patent Application Publication
(10) Pub. No.: US 2009/0127097 A1
(43) Pub. Date: May 21, 2009

(54) Forming Seed Layer in Nano-Trench Structure Using Net Deposition and Net Etch

(76) Inventors: Kei-Wei Chen, Taipei (TW); Shih-Ho Lin, Jhubei (TW); Yu-Sheng Wang, Tainan (TW); Szu-An Wu, Hsin-Chu (TW); Ying-Lang Wang, Taichung (TW)

Correspondence Address: SLATER & MATSIL, L.L.P., 17950 PRESTON ROAD, SUITE 1000, DALLAS, TX, 75252, US

(21) Appl. No.: 11/941,435

(22) Filed: Nov. 16, 2007

(51) Int. Cl. C23C 14/00

(52) U.S. Cl. 204/192.12

(57) ABSTRACT

A method of forming an integrated circuit structure includes forming a dielectric layer; forming an opening in the dielectric layer; performing a net deposition step to form a seed layer having a portion in the opening, wherein the net deposition step comprises a first deposition and a first etching; performing a net etch step to the seed layer, wherein the net etch step comprises a first etching and a first deposition, wherein a portion of the seed layer remains after the net etch step; and growing a conductive material on the seed layer to fill a remaining portion of the opening.

### TECHNICAL FIELD

This invention is related generally to integrated circuits, and more particularly to structures and formation methods of interconnect structures, and even more particularly to the improvement in the step coverage of seed layers.

### BACKGROUND

In integrated circuit art, a commonly used method for forming metal lines and vias is known as “damascene.” Generally, this method involves forming an opening in a dielectric layer, which separates the vertically spaced metallization layers. The opening is typically formed using conventional lithographic and etching techniques. After the formation, the opening is filled with copper or copper alloys. Excess copper on the surface of the dielectric layer is then removed by a chemical mechanical polish (CMP). The remaining copper or copper alloy forms vias and/or metal lines.

Copper is commonly used in the damascene structures because of its low resistivity. Typically, copper is electro plated into damascene openings. As is well known in the art, in order to plate copper, a seed layer is required to provide a low-resistance electrical path (to enable uniform electro-plating over the wafer surface), so that copper ions in the plating solution can be deposited.

FIG. 1 illustrates a cross-sectional view of an intermediate stage in the formation of a conventional damascene structure. Opening 10 is formed in low-k dielectric layer 2, followed by the blanket formation of diffusion barrier layer 4. Next, copper seed layer 6 (including portions 6₁, 6₂, 6₃_{_{—}}₁, and 6₃_{_{—}}₂) is formed, either by physical vapor deposition (PVD), or by electroless plating. FIG. 1 illustrates a typical profile of seed layer 6 formed of PVD. Due to the fact that copper atoms are deposited downwardly, horizontal seed layer portions 6₁ and 6₂, which are over low-k dielectric layer 2 and in opening 10, respectively, are much thicker than portions 6₃ on sidewalls of opening 10. Furthermore, necking effect typically occurs, so that on the sidewalls of opening 10, top portions 6₃_{_{—}}₁ of seed layer 6 is thicker than bottom portions 6₃_{_{—}}₂. The non-uniformity in the profile of seed layer 6 will adversely affect the quality of the subsequently performed electro plating.

One of the methods for reducing the above-discussed profile non-uniformity is to reduce the deposition rate of seed layer 6, for example, using very small power and/or adopting very low pressure in the process chamber. As a result, the throughput becomes very low, and hence this method is not suitable for mass production. New methods for improving the uniformity of seed layers without sacrificing the throughput are thus needed.

### SUMMARY OF THE INVENTION

In accordance with one aspect of the present invention, a method of forming an integrated circuit structure includes forming a dielectric layer; forming an opening in the dielectric layer; performing a net deposition step to form a seed layer having a portion in the opening, wherein the net deposition step comprises a first deposition and a first etching; and growing a conductive material on the seed layer to fill a remaining portion of the opening.

In accordance with another aspect of the present invention, a method of forming an integrated circuit structure includes forming a dielectric layer; forming an opening in the dielectric layer; forming a seed layer having at least a portion in the opening; performing a net etch step to the seed layer, wherein the net etch step comprises a first etching and a first deposition, wherein a portion of the seed layer remains after the net etch step; and growing a conductive material on the seed layer to fill a remaining portion of the opening.

In accordance with yet another aspect of the present invention, a method of forming an integrated circuit structure includes providing a semiconductor substrate; forming a dielectric layer over the semiconductor substrate; forming an opening in the dielectric layer; blanket forming a diffusion barrier layer, wherein the diffusion barrier layer extends into the opening; performing a net deposition step to form a seed layer over the diffusion barrier layer, wherein the net deposition step comprises performing a first deposition and a first etching; after the net deposition step, performing a net etch step to the seed layer, wherein the net etch step comprises simultaneously performing a second etching and a second deposition; and performing an electro plating to form a metallic material on the seed layer, wherein the metallic material fills the opening.

The advantageous features of the present invention include improved conformity of the seed layer, and hence improved quality of the resulting metal lines.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of an intermediate stage in the formation of a conventional damascene structure, which includes a non-conforming seed layer;

FIGS. 2 through 3 and FIGS. 5 through 9 are cross-sectional views of intermediate stages in the manufacturing of an interconnect structure; and

FIG. 4 illustrates a production tool for forming embodiments of the present invention.

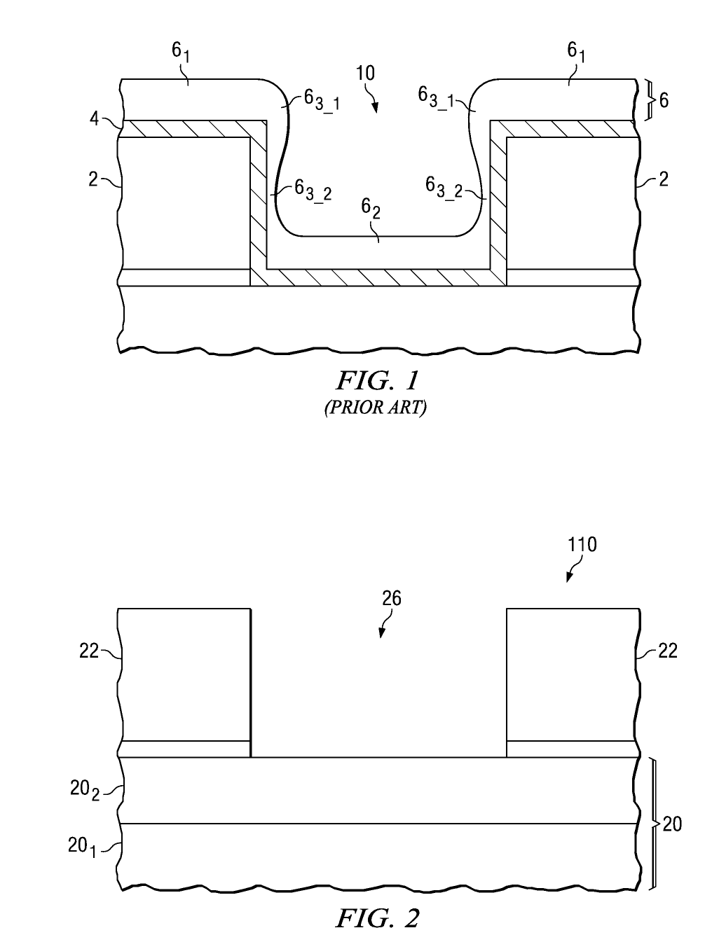

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Methods for forming seed layers with good step coverage are provided. The intermediate stages of manufacturing embodiments of the present invention are illustrated. Throughout various views and illustrative embodiments of the present invention, like reference numbers are used to designate like elements.

Referring to FIG. 2, wafer 110 is provided, which includes schematically illustrated base structure 20, and dielectric 22 over base structure 20. Base structure 20 may include a semiconductor substrate, referred to herein as 20₁, and overlying layers 20₂, which may include a contact etch stop layer (ESL), an inter-layer dielectric (ILD), and inter-metal dielectrics (IMD), in which metallization layers (not shown) are formed. Semiconductor substrate 20₁ may be a single crystalline or a compound semiconductor substrate. Active and passive devices (not shown), such as transistors, resistors, and inductors, may be formed on semiconductor substrate 20₁. Opening 26 is formed in dielectric layer 22. In an exemplary embodiment, opening 26 is a trench opening for forming a metal line, and preferably has a width of less than about 90 nm. Alternatively, opening 26 may be a via opening, a contact opening, or the like.

In an exemplary embodiment, dielectric layer 22 has a low dielectric constant (k value), preferably lower than about 3.0, hence is referred to as low-k dielectric layer 22 throughout the description. More preferably, low-k dielectric layer 22 has a k value of less than about 2.8, and hence is sometimes referred to as an extra low-k (ELK) dielectric layer. Low-k dielectric layer 22 may include commonly used materials such as fluorinated silicate glass (FSG), carbon-containing dielectric materials, and may further contain nitrogen, hydrogen, oxygen, and combinations thereof. A porous structure may exist in low-k dielectric layer 22 for lowering its k value. The thickness of low-k dielectric layer 22 may be between about 1000 Å and about 1 μm. One skilled in the art will realize, however, that the dimensions recited throughout the description are related to the technology used for forming the integrated circuits, and will reduce with the down-scaling of the technology. Low-k dielectric layer 22 may be formed using chemical vapor deposition, spin-on, or other commonly used methods.

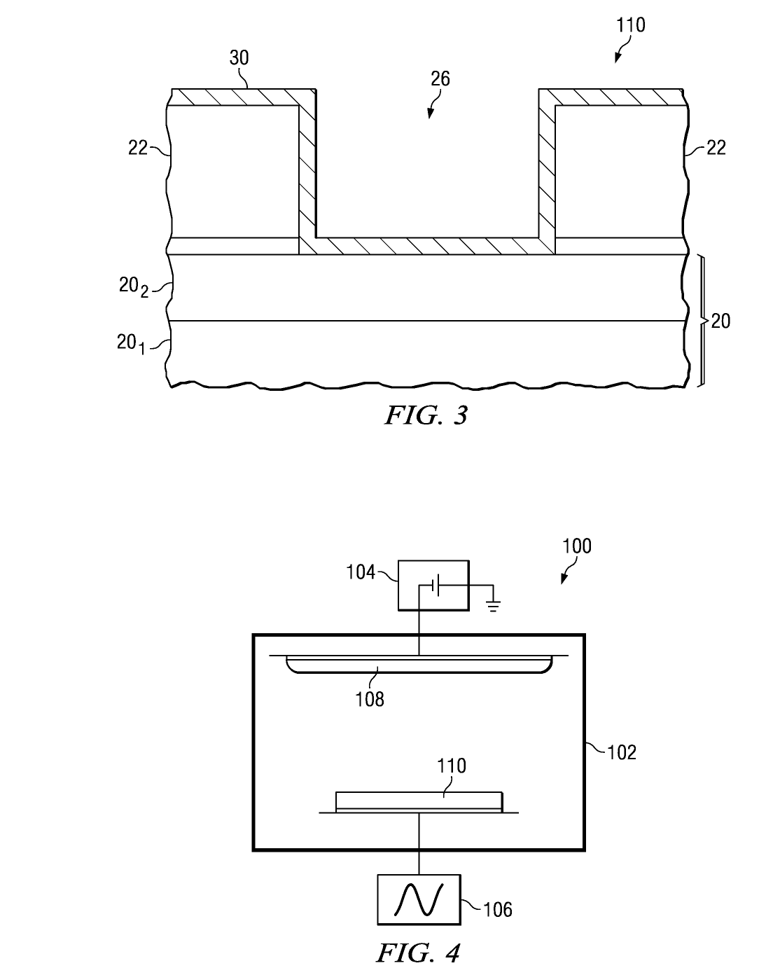

FIG. 3 illustrates the formation of (diffusion) barrier layer 30. Barrier layer 30 preferably includes titanium, tantalum, metal nitride such as titanium nitride and tantalum nitride, or other alternatives, and may be formed using physical vapor deposition (PVD) or one of the chemical vapor deposition (CVD) methods. The thickness of barrier layer 30 may be between about 20 Å and about 200 Å.

Next, a seed layer is formed on barrier layer 30. FIG. 4 illustrates production tool 100 for forming the seed layer. Production tool 100 includes chamber 102 and power sources 104 and 106 connected into chamber 102. Target 108 and wafer 110 are preferably placed facing each other. Target 108 is formed of the desirable materials of the seed layer. Preferably, target 108 includes copper or a copper alloy, which may include aluminum as an alloying material. Alternatively, target 108 may be formed of other metals such as ruthenium or a ruthenium alloy. Wafer 110 includes the structure shown in FIG. 3. Preferably, the process gases in chamber 100 include argon.

Power sources 104 and 106 may be operated independently from each other. Each of the power sources 104 and 106 may be independently powered on or off without affecting each other. Preferably, the connection of each of the power sources 104 and 106 may be switched to either cause a deposition on wafer 110, or cause an etching on wafer 110. As one skilled in art will realize, whether a power source performs a deposition function or an etching function is determined by how the power source is connected to, and to which of the target side or the wafer side. In an exemplary embodiment, a DC power source is connected to target 108 side, and a RF power source is connected to wafer 110 side. Alternatively, the RF power source 106 may be connected to target 108 side, while the DC power source 104 may be connected to wafer 110 side. Power sources 104 and 106 may be replaced by other power sources for bias sputter, magnetron sputter, ion metal plasma (IMP) sputter, and the like, and may be connected in different combinations. For simplicity purpose, in following discussions, the exemplary power source 104 is referred to as a DC power source, and the exemplary power source 106 is referred to as a RF power source. Further, it is assumed the DC power source 104 has its negative end connected to the target 108 side, as is shown in FIG. 4, and hence DC power 104 performs the deposition function. Accordingly, RF power source 106 performs the etching function.

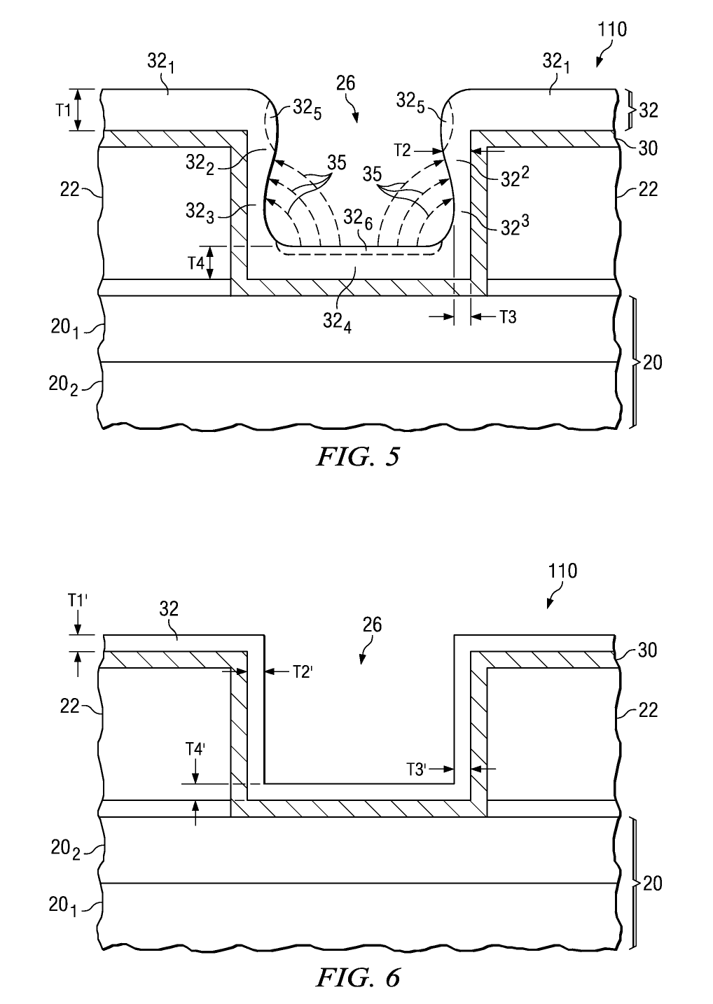

Using production tool 100 as illustrated in FIG. 4, seed layer 32 is formed on barrier layer 30, as is shown in FIG. 5. Optionally, before the formation of seed layer 32, barrier layer 30 is pretreated by turning on RF power source 106, and turning off DC power source 104. RF power source 106 causes a light re-sputter from the surface of wafer 110, which is equivalent to a light etch of barrier layer 30. The pretreatment advantageously improves the surface texture of barrier layer 30, so that the subsequently formed seed layer 32 may be more conformal.

Next, a net deposition step is performed. Preferably, during the net deposition, both power sources 104 and 106 are turned on, and DC power source 104 causes the deposition of the materials of target 108 (refer to FIG. 4) onto wafer 110 to form seed layer 32. Meanwhile, RF power source 106 causes the etching of the deposited seed layer 32. Accordingly, both the deposition and the etching of seed layer 32 occur simultaneously, with the deposition rate greater than the etching rate. The net effect is a net deposition. To incur the net deposition effect, the power of DC power source 104 needs to be greater than the power of RF power source 106. For example, the power of DC power source 104 may be between about 0.5 KW and about 105 KW, while the power of RF power source 106 may be between about 0.1 W and about 1800 W. In an exemplary embodiment, the power of DC power source 104 is about 70 KW, and the power of RF power source 106 is about 100 W.

Seed layer 32 includes portions 32₁ directly over low-k dielectric layer 22, portions 32₂ on sidewalls of, and close to, the top of opening 26, portions 32₃ on sidewalls of, and close to, the bottom of opening 26, and portion 32₄ at the bottom of opening 26. If seed layer 32 is formed by turning RF power source 106 off, the resulting seed layer 32 is typically highly non-conformal (with poor step coverage) with different portions of seed layer 32 have significantly different thicknesses. For example, thicknesses T1 and T4 of respective horizontal portions 32₁ and 32₄ will be significantly greater than thicknesses T2 and T3 of respective vertical portions 32₂ and 32₃. Thickness T2 of portion 32₂ is also typically greater than thickness T3 of portion 32₃, which is referred to as a necking effect. As a comparison, the etching performed by RF power source 106 has the effect of reducing thicknesses T1 and T4, and increasing thickness T3. As a result, seed layer 32 is more conformal than if only DC power source 104 is turned on. It is realized that the power ratio between power sources 104 and 106 affects the resulting profile of seed layer 32. One skilled in the art will be able to find optimum power ratio through experiments.

In alternative embodiments, power sources 104 and 106 may be turned on sequentially, with only one power source turned on at a time. For example, in a net deposition cycle, DC power source 104 is turned on first to deposit a seed layer 32, and then RF power source 106 is turned on to etch a top portion of seed layer 32, wherein the etched top portion has a smaller thickness than what is deposited in the deposition step. During the etch step, the profile of seed layer 32 is improved. The net deposition cycle, including the deposition step and the etching step, may be repeated until the desirable thickness of seed layer 32 is reached.

Although the net deposition step has the effect of improving the step coverage (and conformity) of seed layer 32. The resulting conformity still may not be satisfactory. In the resulting structure (refer to FIG. 5), thicknesses T1 and T4 may still be greater than thicknesses T2 and T3, and thickness T2 may still be greater than thickness T3. A net etch step is thus performed, resulting in a structure shown in FIG. 6. Preferably, the net etch step is in-situ performed in chamber 102 (refer to FIG. 4) with no vacuum break between the net deposition step and the net etch step. The net etch may either be implemented by switching the connection of power sources 104 and 106, or by reducing the power of DC power source 104 to lower than the power of RF power source 106. Accordingly, although in the net etch step, both deposition and etching occur, the etching rate is greater than the deposition rate, and hence the net effect is a net etch. Assuming the connections of power sources 104 and 106 are switched, so that DC power source 104 performs the etching, and RF power source 106 performs the deposition, the power of DC power source 104 may be between about 0.5 KW and about 105 KW, while the power of RF power source 106 may be between about 0.1 W and about 1800 W. In an exemplary embodiment, the power of DC power source 104 is about 1.5 KW, and the power of RF power source 106 is about 1.2 KW.

Referring back to FIG. 5, the net etch step may result in three possible effects; the thicknesses T1 and T4 of seed layer 32 are reduced; the overhang seed layer portions 32₅ are sputtered away; and, a top layer 32₆ of bottom seed layer 32₄ is re-sputtered onto portions 32₃ and possibly portions 32₂, as schematically illustrated by arrows 35. These three effects generate a net effect of thinning thicker portions and thickening thinner portions of seed layer 32. As a result, seed layer 32 has an improved conformity. Experiment results have shown that after the net etch step, the thicknesses T1′, T2′, T3′, and T4′ (refer to FIG. 6) may be substantially the same, even if before the net etch step, thicknesses T1 and T4 to thickness T3 (refer to FIG. 5) may have ratios as high as about 3.

Similar to the net deposition step, the etching and the deposition in the net etch step may be performed sequentially, for example, with an etching step followed by a deposition step. The etching step removes a greater portion of seed layer 32 than when deposited in the deposition step. Also, the etch/deposition cycle in the net etch may be repeated until the desirable result is obtained.

After the net etch step, a second net deposition step may be performed, which may be followed by a second net etch step or a third net deposition step. The cycle of net deposition and net etch may be repeated. The repetition of net deposition steps and net etch steps, which may be in different combinations, eventually results in substantially equal thicknesses T1′, T2′, T3′, and T4′. Advantageously, by dividing one cycle including a net deposition and a net etch into repeated net deposition and net etch cycles, the profile of seed layer 32 may be fixed before excess non-uniformity is formed.

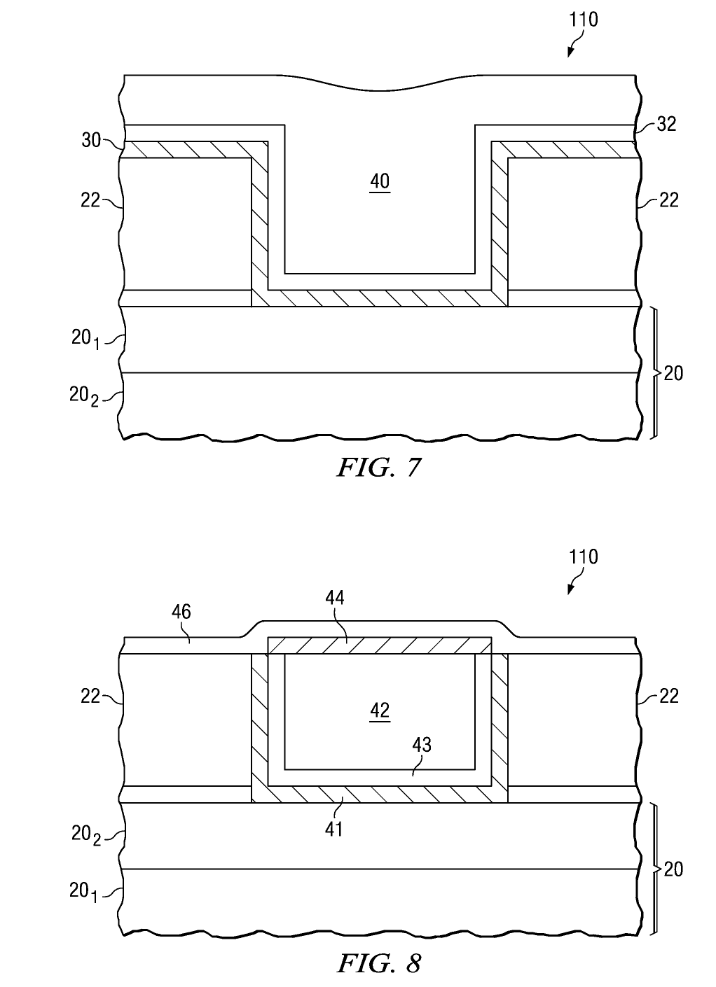

Next, as shown in FIG. 7, copper 40 is filled into the remaining portion of opening 26. In the preferred embodiment, copper 40 is formed using electro plating, wherein wafer 110 is submerged into a plating solution, which contains ionized copper. Due to improved uniformity of seed layer 32, voids are less likely to be formed in opening 26 (refer to FIG. 6).

Referring to FIG. 8, a chemical mechanical polish (CMP) is performed to remove excess portions of copper 40, seed layer 32, and barrier layer 30 over low-k dielectric layer 22, leaving copper line 42 and portions of barrier layer 30 and seed layer 32 in opening 26. The remaining portion of barrier layer 30 and seed layer 32 are referred to as barrier layer 41 and seed layer 43, respectively.

FIG. 8 also illustrates the formation of metal cap 44 and etch stop layer (ESL) 46. Metal cap 44 may be formed of CoWP or other commonly used materials. ESL 46 may be formed of a dielectric material, preferably having a dielectric constant of greater than about 3.5, and may include materials such as silicon nitride, silicon carbide, silicon carbonitride, silicon carbon-oxide, CHₓ, CO_{y}Hₓ, and combinations thereof. The details for forming metal cap 44 and ESL 46 are well known in the art, and hence are not repeated herein.

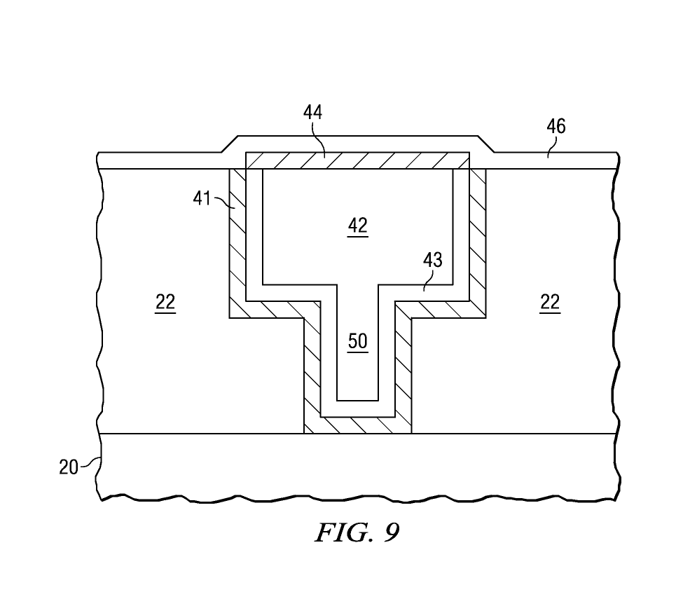

The teaching provided in the preceding paragraphs is readily applicable for use in dual damascene processes. FIG. 9 illustrates a damascene structure, which includes barrier layer 41 and seed layer 43. Seed layer 43 is formed using essentially the same method as taught in preceding paragraphs. Copper line 42 and via 50 are filled in the opening, preferably by electro plating. Similar to the single damascene process, seed layer 43 also has improved conformity, and hence the quality of metal line 42 and via 50 is improved.

The embodiments of the present invention have several advantageous features. By performing net depositions including depositions and etchings, the conformity of the resulting seed layers is significantly improved. The subsequent net etches further improve the conformity of the resulting seed layers. The resulting seed layers are substantially overhang-free. Furthermore, the seed layers may be formed using high power settings, and hence the throughput of manufacturing processes is significantly improved.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming an integrated circuit structure, the method comprising:
forming a dielectric layer;
forming an opening in the dielectric layer;
performing a net deposition step to form a seed layer having a portion in the opening, wherein the net deposition step comprises a first deposition and a first etching; and
growing a conductive material on the seed layer to fill a remaining portion of the opening.

2. The method of claim 1, wherein the first deposition and the first etching are performed simultaneously.

3. The method of claim 1, wherein the first deposition and the first etching are performed in a same chamber, and wherein the first deposition is performed using a first power source, and the first etching is performed using a second power source.

4. The method of claim 1, wherein the first deposition and the first etching are each performed using a method selected from a group consisting essentially of DC sputter, RF sputter, bias sputter, magnetron sputter, and ion metal plasma sputter.

5. The method of claim 1, wherein the first etching is performed after the first deposition.

6. The method of claim 1 further comprising, after the net deposition step, performing a net etch step to the seed layer, wherein the net etch step comprises a second deposition and a second etching.

7. The method of claim 6, wherein the second deposition and the second etching are performed simultaneously.

8. The method of claim 6, wherein the net etch step is in-situ performed with the net deposition step.

9. The method of claim 1 further comprising, before the first net deposition step, forming a diffusion barrier layer in the opening.

10. A method of forming an integrated circuit structure, the method comprising:
forming a dielectric layer;
forming an opening in the dielectric layer;
forming a seed layer having at least a portion in the opening;
performing a net etch step to the seed layer, wherein the net etch step comprises a first etching and a first deposition, wherein a portion of the seed layer remains after the net etch step; and
growing a conductive material on the seed layer to fill a remaining portion of the opening.

11. The method of claim 1, wherein the first deposition and the first etching are performed simultaneously.

12. The method of claim 11, wherein the first deposition and the first etching are performed in a same chamber, and wherein the first deposition is performed using a first power source, and the first etching is performed using a second power source.

13. The method of claim 1, wherein the first etching is performed before the first deposition.

14. The method of claim 1, wherein the net etch is in-situ performed with the step of forming the seed layer.

15. A method of forming an integrated circuit structure, the method comprising:
providing a semiconductor substrate;
forming a dielectric layer over the semiconductor substrate;
forming an opening in the dielectric layer;
blanket forming a diffusion barrier layer, wherein the diffusion barrier layer extends into the opening;
performing a net deposition step to form a seed layer over the diffusion barrier layer, wherein the net deposition step comprises simultaneously performing a first deposition and a first etching;
after the net deposition step, performing a net etch step to the seed layer, wherein the net etch step comprises simultaneously performing a second etching and a second deposition; and
performing an electro plating to form a metallic material on the seed layer, wherein the metallic material fills the opening.

16. The method of claim 15, wherein the first deposition and the first etching are performed in a same chamber, and wherein the first deposition is performed using a first power source, and the first etching is performed using a second power source.

17. The method of claim 16 further comprising, before the step of the net deposition, turning on the second power source and turning off the first power source to perform a pretreatment on a surface of the diffusion barrier layer.

18. The method of claim 16, wherein in the net deposition step, a first power ratio of the first power source to the second power source is greater than one, and wherein in the net etch step, a second power ratio of the first power source to the second power source is less than one.

19. The method of claim 15, wherein the net deposition and the net etch are in-situ performed.

20. The method of claim 15 further comprising, after the step of performing the net etch step, performing a second net deposition step comprising simultaneously performing a third deposition and a third etch.
